(19) United States
(12) Patent Application Publication
(10) Pub. No.: US 2010/0308457 A1
(43) Pub. Date: Dec. 9, 2010

(54) Semiconductor apparatus and manufacturing method of the same

(75) Inventor: Kenichi Ishii, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/662,332

(22) Filed: Apr. 12, 2010

(30) Foreign Application Priority Data
Jun. 3, 2009 (JP) 2009-133940

(51) Int. Cl. H01L 23/498; H01L 21/60; H01L 23/488; H01L 23/49

(52) U.S. Cl. 257/737; 438/119; 257/779; 257/784; 257/E21.514; 257/E23.024; 257/E23.06; 257/E23.023

(57) ABSTRACT

Provided is a semiconductor apparatus that reduces on-resistance in wiring between a first electrode terminal and a second electrode terminal. The semiconductor apparatus includes the first electrode terminal, the second electrode terminal, and at least two wires that connect the first and second electrode terminals. At least two wires are electrically connected with each other by using a conductive adhesive in an extending direction of the wires. The first electrode terminal is a terminal of an external lead electrode, for example. The second electrode terminal is a terminal of a source electrode of a MOSFET, for example.

### INCORPORATION BY REFERENCE

This application is based upon and claims the benefit of priority from Japanese patent application No. 2009-133940, filed on Jun. 3, 2009, the disclosure of which is incorporated herein in its entirety by reference.

### BACKGROUND

1. Field of the Invention

The present invention relates to a semiconductor apparatus and a manufacturing method of the same.

2. Description of Related Art

Recently, technology related to lower power consumption and higher efficiency of a semiconductor apparatus has received attention for achieving the low power consumption society. Particularly, in a power metal-oxide-semiconductor field effect transistor (MOSFET) or the like which is used in the power electronics field, a technique of reducing on-resistance is used to reduce power consumption.

An aluminum (Al) wire with a diameter of 100 μm to 500 μm is generally used for connection of a power device of a semiconductor apparatus such as a power MOSFET. FIG. 6 is a plan view showing an example of implementation inside a semiconductor apparatus according to prior art. Referring to FIG. 6, the semiconductor apparatus includes a lead frame 41, a semiconductor chip 42, wires 43 and 44, a sealing resin 45, a source electrode 46, and an external lead electrode 47. In the semiconductor apparatus shown in FIG. 6, the source electrode 46 and the external lead electrode 47 are connected by using a plurality of wires 43, thereby reducing on-resistance in wiring. It is thus possible to suppress heat and power loss even when a large current flows between the source electrode 46 and the external lead electrode 47.

FIG. 7 is a plan view showing another example of implementation inside a semiconductor apparatus according to prior art. Referring to FIG. 7, the semiconductor apparatus includes a lead frame 51, a semiconductor chip 52, a thin plate 53, a wire 54, a sealing resin 55, a junction part 56, a source electrode 57 and an external lead electrode 58. In the semiconductor apparatus shown in FIG. 7, the source electrode 57 of the semiconductor chip 52 and the external lead electrode 58 are connected by using the thin plate 53 instead of a wire, thereby reducing on-resistance in wiring to several mΩ. It is thus possible to suppress heat and power loss when a large current flows between the source electrode 57 and the external lead electrode 58.

Reduction of on-resistance in wiring contributes to cooling of applied equipment or reduction of power consumption. Further, the characteristics are significantly affected by the performance of a device itself or a package serving as an interface between a device and an external circuit.

Japanese Unexamined Patent Application Publication No. 2001-036001 discloses a technique related to a power semiconductor module that uses a net thin metal line in at least part of wiring for electrically connecting an electrode terminal that establishes an electrical connection with the outside and a semiconductor chip. Because the net thin metal line has a larger surface area and higher heat dissipating efficiency than a thin metal line, it is possible to efficiently cool the semiconductor chip.

Japanese Unexamined Patent Application Publication No. 2007-317718 discloses a technique related to a wire bonding structure in which the middle parts of a plurality of wires whose both ends are connected to electrodes are connected to a common lead.

### SUMMARY

However, in the case of using the plurality of wires 43 as shown in FIG. 6, the number of wires 43 which can be used is limited because there is a limit to narrow the interval between the wires 43. Further, if the diameter of the wire 43 is increased, it is necessary to bond the semiconductor chip 42 and the wires 43 with use of a large ultra sonic (US) power, pressure or the like, which increases the possibility of breaking of the semiconductor chip 42, making it difficult to maintain the stable quality.

Further, in the case of using the thin plate 53 as shown in FIG. 7, both surfaces of the semiconductor chip 52 are joined over a wide area by materials with different thermal expansion coefficients. Thus, an excessive thermal stress is applied to the junction part 56, which increases the possibility of breaking of the semiconductor chip 52.

In the technique disclosed in Japanese Unexamined Patent Application Publication No. 2001-036001, a larger power is required for bonding of the semiconductor chip and the net thin metal line compared to bonding of the semiconductor chip and the metal thin metal line, which increases the possibility of breaking of the semiconductor chip. Further, it is necessary to separately prepare the net thin metal line, which causes the cost to increase.

The technique disclosed in Japanese Unexamined Patent Application Publication No. 2007-317718 does not aim to reduce on-resistance in wiring. Further, because the technique performs bonding by deforming a plurality of bonding wires to be pressed against the common lead, the area of the common lead becomes larger, and a step of deforming the bonding wires is necessary, which causes the cost to increase.

An exemplary aspect of the present invention is a semiconductor apparatus which includes a first electrode terminal, a second electrode terminal, and at least two wires that connect the first electrode terminal and the second electrode terminal, wherein the at least two wires are electrically connected with each other by using a conductive adhesive in an extending direction of the at least two wires.

An exemplary aspect of the present invention is a manufacturing method of a semiconductor apparatus which includes connecting a first electrode terminal and a second electrode terminal by using at least two wires, and electrically connecting the at least two wires with each other by using a conductive adhesive in an extending direction of the at least two wires.

According to the exemplary aspect of the present invention described above, at least two wires are electrically connected with each other by using a conductive adhesive in a direction along which at least two wires extend, thereby reducing on-resistance in wiring between the first electrode terminal and the second electrode terminal.

According to the exemplary aspect of the present invention described above, it is possible to achieve lower power consumption and higher efficiency of a semiconductor apparatus by reducing on-resistance in wiring.

### BRIEF DESCRIPTION OF THE DRAWINGS

The above and other exemplary aspects, advantages and features will be more apparent from the following description of certain exemplary embodiments taken in conjunction with the accompanying drawings, in which:

FIGS. 1A and 1B are views showing a semiconductor apparatus according to a first exemplary embodiment of the invention; specifically, FIG. 1A is a plan view of the semiconductor apparatus and FIG. 1B is a sectional view of the semiconductor apparatus along line IB-IB in FIG. 1A;

FIG. 2 is a flowchart showing a manufacturing process of the semiconductor apparatus according to the first exemplary embodiment of the invention;

FIGS. 3A and 3B are views showing a semiconductor apparatus according to a second exemplary embodiment of the invention; specifically, FIG. 3A is a plan view of the semiconductor apparatus and FIG. 3B is a sectional view of the semiconductor apparatus along line IIIB-IIIB in FIG. 3A;

FIG. 4 is a plan view of a semiconductor apparatus according to a third exemplary embodiment of the invention;

FIG. 5 is a plan view of a power module according to a fourth exemplary embodiment of the invention;

FIG. 6 is a plan view showing an example of implementation inside a semiconductor apparatus according to prior art; and

FIG. 7 is a plan view showing another example of implementation inside a semiconductor apparatus according to prior art.

### DETAILED DESCRIPTION OF THE EXEMPLARY EMBODIMENTS

### First Exemplary Embodiment

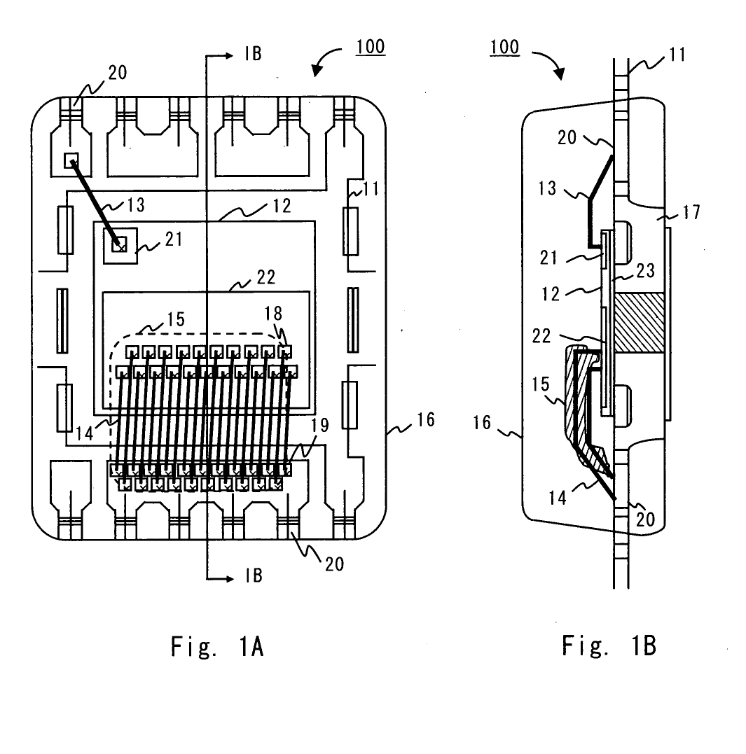

A structure of a semiconductor apparatus 100 according to a first exemplary embodiment of the invention is described hereinafter with reference to FIGS. 1A and 1B. FIG. 1A is a plan view of the semiconductor apparatus 100 when viewed from above, and FIG. 1B is a sectional view of the semiconductor apparatus 100 along line IB-IB in FIG. 1A. Structural elements of the semiconductor apparatus 100 and a manufacturing method of the semiconductor apparatus 100 are described in detail later.

The semiconductor apparatus 100 according to the first exemplary embodiment includes a lead frame 11, a semiconductor chip 12, wires 13 and 14, a conductive adhesive 15, and a sealing resin 16.

The lead frame 11 has an island 17, and the island 17 is joined to a drain electrode 23 of the semiconductor chip 12. Further, the lead frame 11 has an external lead electrode 20. The lead frame 11 is a thin-film metal that is used as internal wiring of a semiconductor package, and it act as a bridge with external wiring.

The semiconductor chip 12 has a gate electrode 21 and a source electrode 22. The semiconductor chip 12 is typically a MOSFET. Alternatively, it may be a bipolar transistor, a diode, an insulated gate bipolar transistor (IGBT), a silicon carbide (SiC) device, a gallium nitride (GaN) device, or a normal integrated circuit (IC).

The wire 13 electrically connects the gate electrode 21 and the external lead electrode 20. Because there is no need to flow a large current to the gate electrode 21, one wire 13 is used for connection.

The wire 14 is typically a thin line with a diameter of less than 100 μm. As shown in FIG. 1A, the source electrode 22 and each wire 14 are electrically connected at a connection part 18. Further, the external lead electrode 20 and each wire 14 are electrically connected at a connection part 19. In this manner, the wire 14 electrically connects the source electrode 22 and the external lead electrode 20. The number of a plurality of wires 14 that connect the source electrode 22 and the external lead electrode 20 is at least two, and the resistance between the source electrode 22 and the external lead electrode 20 decreases as the number of wires 14 increases.

Further, as shown in FIG. 1A, the connection parts 18 of the source electrode 22 and the connection parts 19 of the external lead electrode 20 may be respectively arranged in two staggered rows, or arranged in one row if the interval between the connection parts 18 or 19 can be narrowed. Further, as shown in FIG. 1A, the plurality of wires 14 are arranged substantially in parallel with each other.

The conductive adhesive 15 is applied to at least two wires 14 in the direction along which at least two wires 14 extend, so that the wires 14 are electrically connected with each other. This enables reduction of on-resistance in wiring between the source electrode 22 and the external lead electrode 20. Further, a metal paste may be used instead of the conductive adhesive 15, and it is desirable that the conductive adhesive 15 or the metal paste has appropriate viscosity and thixotropy enough to stick on at least two wires 14. Furthermore, a metal sheet or solder may be used instead of the conductive adhesive 15.

The sealing resin 16 is applied in order to protect the semiconductor chip 12 or the like from light, heat, humidity and so on, and it packages the semiconductor apparatus 100.

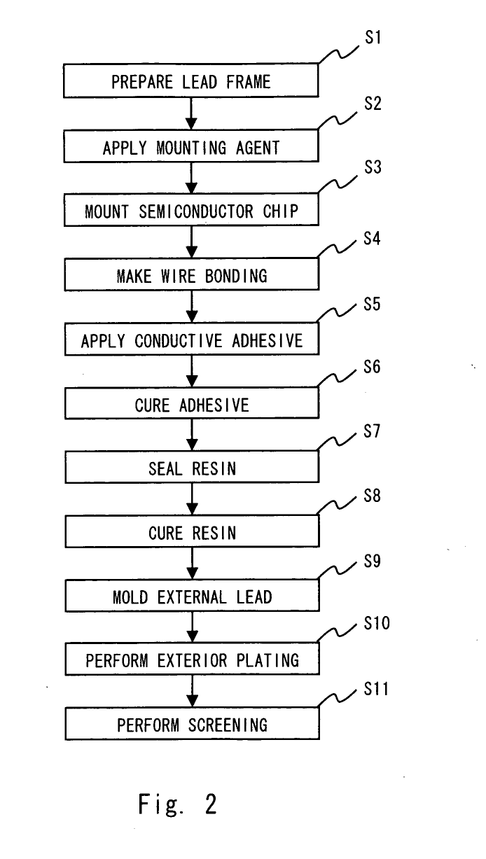

A manufacturing method of the semiconductor apparatus 100 is described hereinafter with reference to the flowchart of FIG. 2.

First, the lead frame 11 is prepared (step S1). Next, a mounting agent is applied to the lead frame 11 (step S2), and the semiconductor chip 12 is mounted in such a way that the drain electrode 23 of the semiconductor chip 12 is joined to the island 17 of the lead frame 11 (step S3).

Then, both ends of the wire 13 are bonded respectively to the external lead electrode 20 and the gate electrode 21. Further, both ends of the plurality of wires 14 are bonded respectively to the external lead electrode 20 and the source electrode 22 (step S4).

Then, the conductive adhesive 15 is applied in the direction along which the plurality of Wires 14 extend, so that the plurality of wires 14 are electrically connected with each other (step S5). In the case of using a metal sheet instead of the conductive adhesive 15, the metal sheet is adhered to the wires 14 by setting the metal sheet on top of the wires 14 and heating them, for example, so that the plurality of wires 14 are electrically connected with each other.

Further, a curing agent or the like is added to the applied conductive adhesive 15 to thereby cure the conductive adhesive 15 (step S6).

Then, the sealing resin 16 is applied to the semiconductor apparatus 100 to thereby seal the apparatus (step S7). Further, a curing agent or the like is added to the applied sealing resin 16 to thereby cure the sealing resin 16 (step S8).

After that, an external lead of the semiconductor apparatus 100 is molded (step S9).

Finally, exterior plating is performed in the semiconductor apparatus 100 (step S10), and the finished semiconductor apparatus 100 are screened (step S11).

As described above, because a plurality of wires are electrically connected with each other by using a conductive adhesive in the semiconductor apparatus according to the exemplary embodiment, it is possible to reduce on-resistance in wiring for connecting the electrode of the semiconductor chip and the external lead electrode.

Further, because a thin line is used as the wire 14 in the above-described semiconductor apparatus, it is possible to bond the source electrode 22 and the wire 14 with an appropriate US power. It is thereby possible to reduce on-resistance in wiring without placing an excessive load on the semiconductor chip 12.

Further, the wire 14 is resistant to stress because it does not lose flexibility, and degradation of reliability due to a difference in thermal expansion coefficient between materials can be prevented. Furthermore, there is no need to perform a step of deforming the wire 14, which allows cost reduction.

### Second Exemplary Embodiment

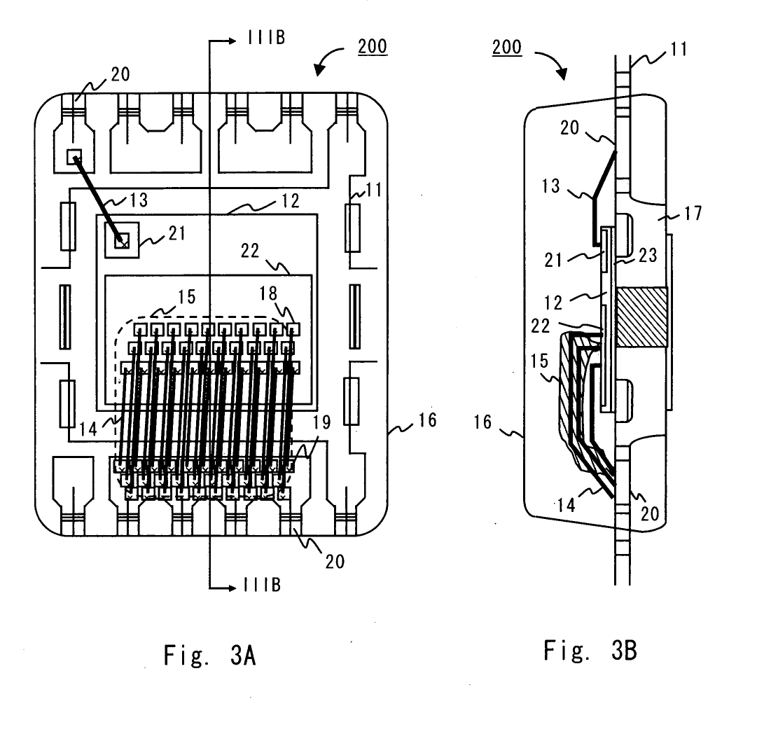

A structure of a semiconductor apparatus 200 according to a second exemplary embodiment of the invention is described hereinafter with reference to FIGS. 3A and 3B. FIG. 3A is a plan view of the semiconductor apparatus 200 when viewed from above, and FIG. 3B is a sectional view of the semiconductor apparatus 200 along line IIIB-IIIB in FIG. 3A. The structure of the semiconductor apparatus 200 according to the exemplary embodiment is the same as the structure of the semiconductor apparatus 100 according to the first exemplary embodiment except for the arrangement of the wires 14, and description of equivalent elements is omitted.

In the semiconductor apparatus 200 according to the second exemplary embodiment, a plurality of wires 14 are arranged substantially in parallel with each other. Further, as shown in FIG. 3A, the connection parts 18 of the source electrode 22 and the wires 14 and the connection parts 19 of the external lead electrode 20 and the wires 14 are respectively arranged in m (m is an integer of two or greater) and n (n is an integer of two or greater) rows. By arranging the connection parts 18 and 19 in this manner, the interval between the plurality of wires 14 is narrowed, so that the adhesiveness of the conductive adhesive 15 increases. The semiconductor apparatus 200 shown in FIGS. 3A and 3B is an example in which the wires 14 are arranged substantially in parallel with each other in three rows.

The conductive adhesive 15 is applied to at least two wires 14 in the direction along which at least two wires 14 extend, so that the wires 14 are electrically connected with each other. This enables reduction of on-resistance in wiring between the source electrode 22 and the external lead electrode 20. Further, a metal paste may be used instead of the conductive adhesive 15, and it is desirable that the conductive adhesive 15 or the metal paste has appropriate viscosity and thixotropy enough to stick on at least two wires 14. Furthermore, a metal sheet or solder may be used instead of the conductive adhesive 15.

As described above, because a plurality of wires are electrically connected with each other by using a conductive adhesive in the semiconductor apparatus according to the exemplary embodiment, it is possible to reduce on-resistance in wiring for connecting the electrode of the semiconductor chip and the external lead electrode.

Particularly, the interval between wires can be narrowed in the semiconductor apparatus according to the exemplary embodiment, and it is thus possible to widen the area of the conductive adhesive 15 to be applied.

### Third Exemplary Embodiment

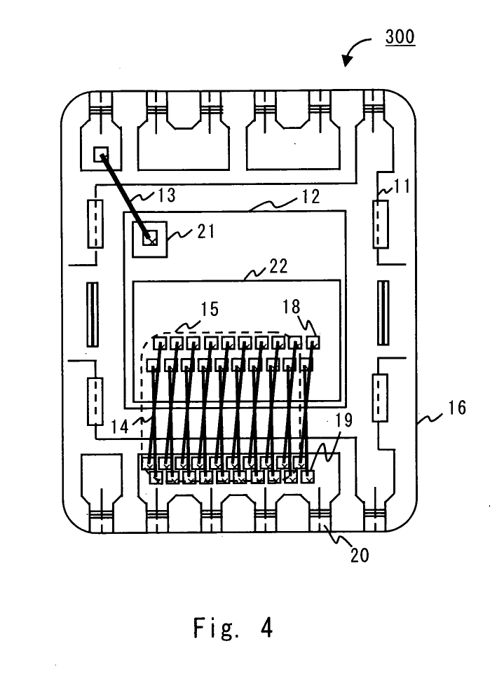

A structure of a semiconductor apparatus 300 according to a third exemplary embodiment of the invention is described hereinafter with reference to FIG. 4. The structure of the semiconductor apparatus 300 according to the exemplary embodiment is the same as the structure of the semiconductor apparatus 100 according to the first exemplary embodiment except for the arrangement of the wires 14, and description of equivalent elements is omitted.

In the semiconductor apparatus 300 according to the third exemplary embodiment, the plurality of wires 14 are arranged to intersect with each other or arranged in a skew relation in order to particularly narrow part of the interval between the plurality of wires 14. It is assumed that the wires 14 intersecting with each other are in contact with each other. It is also assumed that the wires 14 in a skew relation are not in contact with each other. The semiconductor apparatus 300 shown in FIG. 4 is an example in which every two wires 14 intersect with each other.

The conductive adhesive 15 is applied to at least two wires 14 in the direction along which at least two wires 14 extend, so that the wires 14 are electrically connected with each other. This enables reduction of on-resistance in wiring between the source electrode 22 and the external lead electrode 20. Further, a metal paste may be used instead of the conductive adhesive 15, and it is desirable that the conductive adhesive 15 or the metal paste has appropriate viscosity and thixotropy enough to stick on at least two wires 14. Furthermore, a metal sheet or solder may be used instead of the conductive adhesive 15.

As described above, because a plurality of wires are electrically connected with each other by using a conductive adhesive in the semiconductor apparatus according to the exemplary embodiment, it is possible to reduce on-resistance in wiring for connecting the electrode of the semiconductor chip and the external lead electrode.

Particularly, the interval between wires can be narrowed in the semiconductor apparatus according to the exemplary embodiment, and it is thus possible to widen the area of the conductive adhesive 15 to be applied.

### Fourth Exemplary Embodiment

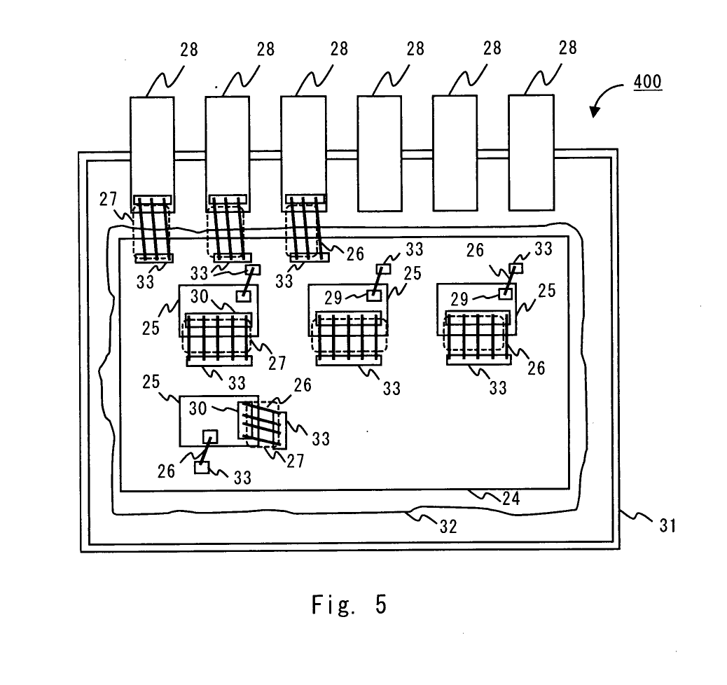

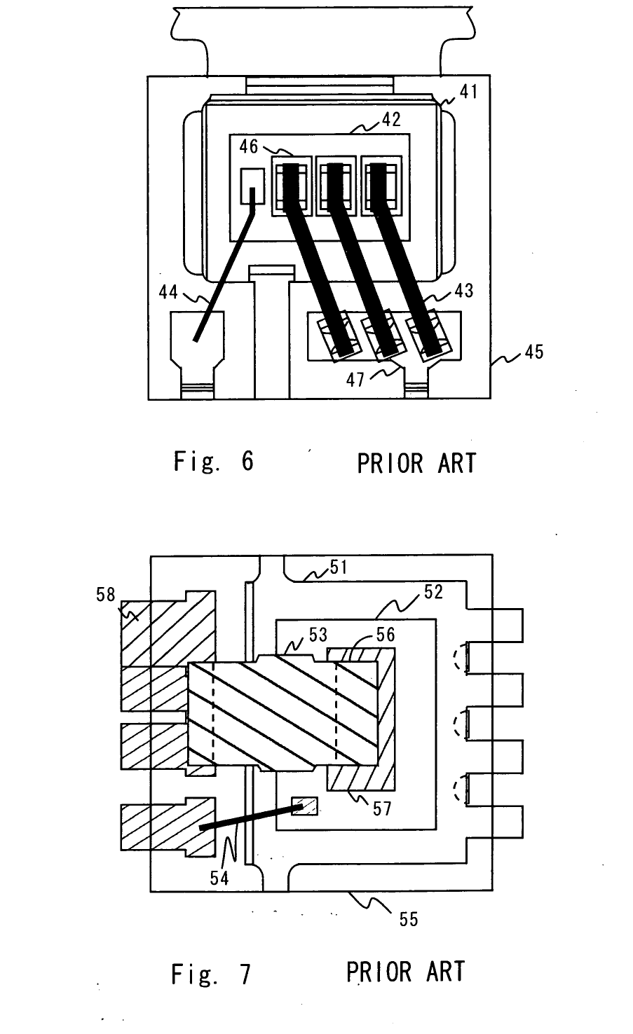

A structure of a power module 400 according to a fourth exemplary embodiment of the invention is described hereinafter with reference to FIG. 5.

The power module 400 according to the fourth exemplary embodiment is mainly applied to a power device such as IGBT, and it includes a base 31, a ceramic substrate 24, a semiconductor chip 25, a wire 26, a conductive adhesive 27, and an external lead electrode 28.

The base 31 is typically a cooling plate, and copper, aluminum or the like is used as its material.

The ceramic substrate 24 is adhered to the base 31 by an adhesive 32. Further, the ceramic substrate 24 has an electrical circuit, and a plurality of semiconductor chips 25 are mounted on the ceramic substrate 24. Note that the ceramic substrate 24 may be another insulating substrate.

The semiconductor chip 25 has a gate electrode 29 and a source electrode 30.

The wire 26 makes an electrical connection between an electrode terminal 33 of the electrical circuit and the gate electrode 29, between the electrode terminal 33 of the electrical circuit and the source electrode 30, and between the electrode terminal 33 of the electrical circuit and the external lead electrode 28.

The conductive adhesive 27 is applied to at least two wires 26 arranged substantially in parallel with each other in the direction along which at least two wires 26 extend, so that the wires 26 are electrically connected with each other. This enables reduction of on-resistance in wiring between the external lead electrode 28 and the electrode terminal 33 of the electrical circuit and between the electrode terminal 33 of the electrical circuit and the source electrode 30. A metal paste may be used instead of the conductive adhesive 27, and it is desirable that the conductive adhesive 27 or the metal paste has appropriate viscosity and thixotropy enough to stick on at least two wires 26. Furthermore, a metal sheet or solder may be used instead of the conductive adhesive 27.

The external lead electrode 28 is electrically connected to the electrode terminal of the electrical circuit by the wires 26. Further, the external lead electrode 28 is electrically connected to an electrode (not shown) existing outside the power module 400.

As described above, in the power module according to the exemplary embodiment, because a plurality of wires are electrically connected with each other by using a conductive adhesive, it is possible to reduce on-resistance in wiring between the external lead electrode and the electrode terminal of the electrical circuit and between the electrode terminal of the electrical circuit and the source electrode.

The present invention is not limited to the above-described exemplary embodiments but may be varied in many ways without departing from the scope of the invention.

The first to fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor apparatus comprising:
a first electrode terminal;
a second electrode terminal; and
at least two wires that connect the first electrode terminal and the second electrode terminal, wherein
the at least two wires are electrically connected with each other by using a conductive adhesive in an extending direction of the at least two wires.

2. The semiconductor apparatus according to claim 1, wherein the conductive adhesive has viscosity and thixotropy.

3. The semiconductor apparatus according to claim 1, wherein the conductive adhesive is a metal paste.

4. The semiconductor apparatus according to claim 1, wherein the conductive adhesive is a metal sheet.

5. The semiconductor apparatus according to claim 1, wherein the conductive adhesive is a solder.

6. The semiconductor apparatus according to claim 1, wherein the at least two wires are arranged substantially in parallel with each other.

7. The semiconductor apparatus according to claim 1, wherein the at least two wires are arranged to intersect with each other.

8. The semiconductor apparatus according to claim 1, wherein the at least two wires are arranged in a skew relation.

9. The semiconductor apparatus according to claim 1, wherein the first electrode terminal is a terminal of an external lead electrode, and the second electrode terminal is a terminal of a source electrode.

10. The semiconductor apparatus according to claim 1, wherein the first electrode terminal is a terminal of an external lead electrode, and the second electrode terminal is an electrode terminal of an electrical circuit.

11. The semiconductor apparatus according to claim 1, wherein the first electrode terminal is a terminal of a source electrode, and the second electrode terminal is an electrode terminal of an electrical circuit.

12. The semiconductor apparatus according to claim 1, wherein the first electrode terminal is an electrode terminal of any one of a metal-oxide-semiconductor field effect transistor (MOSFET), a bipolar transistor, a diode, an insulated gate bipolar transistor (IGBT), and a MOSFET formed by using silicon carbide (SiC) or gallium nitride (GaN).

13. A manufacturing method of a semiconductor apparatus comprising:
connecting a first electrode terminal and a second electrode terminal by using at least two wires; and
electrically connecting the at least two wires with each other by using a conductive adhesive in an extending direction of the at least two wires.

14. The manufacturing method of a semiconductor apparatus according to claim 13, further comprising:
curing the conductive adhesive.
